(19) United States
(12) Patent Application Publication
(10) Pub. No.: US 2006/0203538 A1
(43) Pub. Date: Sep. 14, 2006

(54) Magnetoresistive effect element and magnetic memory

(75) Inventor: Keiji Koga, Tokyo (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 11/330,175

(22) Filed: Jan. 12, 2006

(30) Foreign Application Priority Data
Jan. 13, 2005 (JP) P2005-006634

(51) Int. Cl. G11C 11/00; G11C 11/14; G11C 11/15; G11B 5/33; G11B 5/127

(52) U.S. Cl. 365/158; 360/324.2; 365/171; 365/173

(57) ABSTRACT

A TMR element has a free first magnetic layer, a second magnetic layer with a fixed magnetization direction provided above one surface of the first magnetic layer, a nonmagnetic insulating layer provided between the first magnetic layer and the second magnetic layer, a third magnetic layer with a fixed magnetization direction provided above another surface of the first magnetic layer, and a first nonmagnetic conductive layer provided between the first magnetic layer and the third magnetic layer. An electric resistance per cross section of 1 μm² perpendicular to a stack direction, between two ends in the stack direction, is not less than 1 Ω nor more than 100 Ω.

### BACKGROUND OF THE INVENTION

1. Field of the Invention

The present invention relates to a magnetoresistive effect element and a magnetic memory for storing data in the magnetoresistive effect elements.

2. Related Background Art

An MRAM (Magnetic Random Access Memory) with magnetoresistive effect elements is presently drawing attention as a storage device used in information processing apparatus such as computers and communication equipment. The MRAM is a type of memory that stores data by magnetism, and is thus free of such inconvenience that information is lost with power discontinuity, different from the DRAM (Dynamic Random Access Memory) and SRAM (Static RAM) being volatile memories. In addition, the MRAM is much superior in access speed, reliability, power consumption, etc. to nonvolatile storage means such as the conventional flash EEPROM (Electronically Erasable and Programmable Read Only Memory) and hard disk drives. Therefore, the MRAM holds the potential to replace all the function of the volatile memories such as the DRAM and SRAM and the function of the nonvolatile storage means such as the flash EEPROM and hard disk drives. Nowadays, there are rapidly ongoing efforts to develop information equipment aiming at so-called ubiquitous computing to enable information processing anytime and anywhere, and the MRAM is expected to play a role as a key device in such information equipment.

An example of the MRAM is a memory making use of the tunneling magnetoresistive (TMR) effect, for example. The TMR effect is a phenomenon in which the resistance between two ferromagnetic layers varies according to a relative angle between magnetization directions of the two ferromagnetic layers with a thin insulating layer in between. Namely, the resistance becomes minimum when the magnetization directions of the two ferromagnetic layers are parallel to each other, and becomes maximum when they are antiparallel. By making use of this TMR effect, a resistance change rate of the magnetoresistive effect element can be 40% or more, for example. In addition, since the resistance is relatively high, it is easy to combine the TMR element with a semiconductor device such as a MOS-FET. Accordingly, stored data can be stably read out by a relatively small electric current, and there are thus great hopes for increase in storage capacity and for improvement in operation speed.

An MRAM using the TMR effect is a magnetic memory disclosed, for example, in Patent Document 1 (Japanese Patent Application Laid-Open No. 2004-153182).

### SUMMARY OF THE INVENTION

The MRAM using the TMR effect has a lot of advantages as described above. However, the currently available MRAMs are constructed to vary the direction of magnetization in one ferromagnetic layer (magnetosensitive layer) by a magnetic field generated by an electric current flowing in a write line disposed near the TMR element, as is the case in the configuration disclosed in Patent Document 1. In this configuration, the magnetic field of the electric current from the write line is also radiated into directions except for the direction toward the TMR element as an object to be written, and it can cause erroneous writing in other TMR elements.

Furthermore, where the direction of magnetization in the magnetosensitive layer is varied by the magnetic field of the electric current from the write line, a demagnetizing field will increase inside the magnetosensitive layer with decrease in a ratio of planar size to thickness of the magnetosensitive layer. Accordingly, as the size of the TMR element is decreased in order to achieve higher integration of the MRAM, the magnetic field strength necessary for varying the direction of magnetization in the magnetosensitive layer increases, so as to require a large write current. For this reason, achievement of higher integration is difficult with the MRAM in the configuration to vary the direction of magnetization in the magnetosensitive layer by the magnetic field of the electric current.

The present invention has been accomplished in view of the problem described above, and an object of the invention is to provide a magnetoresistive effect element and a magnetic memory capable of preventing erroneous writing and facilitating achievement of higher integration.

In order to solve the above problem, a magnetoresistive effect element according to the present invention is a magnetoresistive effect element comprising: a first magnetic layer which contains a ferromagnetic material and a magnetization direction of which varies according to a density and a spin direction of an electric current flowing in a stack direction; a second magnetic layer which contains a ferromagnetic material, which is provided above one surface of the first magnetic layer, and a magnetization direction of which is fixed; a nonmagnetic insulating layer which contains a nonmagnetic and insulating material and which is provided between the first magnetic layer and the second magnetic layer; a third magnetic layer which contains a ferromagnetic material, which is provided above another surface of the first magnetic layer, and a magnetization direction of which is fixed; and a first nonmagnetic conductive layer which contains a nonmagnetic and electrically conductive material and which is provided between the first magnetic layer and the third magnetic layer, wherein an electric resistance between two ends in the stack direction per cross section of 1 μm² perpendicular to the stack direction is not less than 1Ω nor more than 100Ω.

In the above-described magnetoresistive effect element, the first nonmagnetic conductive layer is provided between the first magnetic layer with the varying magnetization direction and the third magnetic layer with the fixed magnetization direction. When an electric current 20 is allowed to -flow in the stack direction in the laminate of this configuration, the spin direction of the electric current is filtered at the interface (junction) between the third magnetic layer and the first nonmagnetic conductive layer, to generate a spin-polarized current with the spin direction biased. When the spin-polarized current over a 25 certain current density flows in the first magnetic layer, it causes a change in the magnetization direction of the first magnetic layer (magnetization reversal).

In the above-described magnetoresistive effect element, as described above, the magnetization direction of the first magnetic layer can be changed by the direct flow of the electric current in the magnetoresistive effect element, instead of the external magnetic field like the magnetic field of the electric current. In addition, the spin-polarized current is generated by the third magnetic layer and the first nonmagnetic conductive layer, so that the magnetization direction can be varied by the relatively small electric current. Therefore, the above-described magnetoresistive effect element is able to prevent erroneous writing in TMR elements other than the TMR element as an object to be written.

In the above-described magnetoresistive effect element, the magnetization direction is varied by the spin-polarized current; therefore, it prevents increase in the demagnetizing field inside the first magnetic layer and, in addition, the smaller the planar size of the first magnetic layer, the smaller the electric current necessary for the variation of the magnetization direction. Therefore, the above-described magnetoresistive effect element facilitates miniaturization thereof and also facilitates achievement of higher integration of a device, e.g., an MRAM provided with such magnetoresistive effect elements.

In the aforementioned magnetoresistive effect element, the nonmagnetic insulating layer is provided between the first magnetic layer with the varying magnetization direction and the second magnetic layer with the fixed magnetization direction. This produces the TMR effect between the first magnetic layer and the second magnetic layer and achieves a relatively large resistance change rate by the variation in the magnetization direction of the first magnetic layer. Therefore, it is feasible to quickly and stably read out data stored by the magnetization direction of the first magnetic layer.

Furthermore, in the foregoing magnetoresistive effect element, the electric resistance between two ends in the stack direction per cross section of 1 μm² perpendicular to the stack direction is not less than 1Ω nor more than 100Ω. For achieving the magnetization reversal by the spin-polarized current, it is necessary to apply a relatively large current, e.g., 1×10⁷ A/cm². In the conventional TMR elements on the other hand, a large resistance was set (within the scope where the TMR effect is achieved) for the nonmagnetic insulating layer between the two ferromagnetic layers in order to obtain a large resistance change rate. Accordingly, where the spin injection method is applied to the conventional TMR elements, power consumption will be too large and the element temperature will be so high as to induce significant degradation of performance due to electromigration. In addition, an excessive potential difference is generated between the upper and lower surfaces of the nonmagnetic insulating layer, which could cause breakage of the nonmagnetic insulating layer.

Concerning this problem, the Inventor discovered that when the electric resistance between two ends in the stack direction of the magnetoresistive effect element was not less than 1 Ωμm² nor more than 100 Ωμm², the aforementioned advantage by the TMR effect was also achieved while appropriately effecting the magnetization reversal by the spin-polarized current. Therefore, the aforementioned magnetoresistive effect element is able to prevent erroneous writing in the TMR elements other than the object to be written, due to the magnetization reversal by the spin-polarized current, to facilitate achievement of higher integration of the device, and to quickly and stably read out data (magnetization direction) stored in the first magnetic layer, by the TMR effect.

The magnetoresistive effect element may be characterized in that a thickness of the second magnetic layer in the stack direction is larger than a thickness of the first magnetic layer in the stack direction. The magnetoresistive effect element may also be characterized in that an area of a cross section of the second magnetic layer perpendicular to the stack direction is larger than an area of a cross section of the first magnetic layer perpendicular to the stack direction. At least one of these configurations can effectively prevent disturbance of the magnetization direction of the second magnetic layer due to the electric current for varying the magnetization direction of the first magnetic layer, and stably retain the magnetization direction of the second magnetic layer.

The magnetoresistive effect element may also be characterized in that a thickness of the third magnetic layer in the stack direction is larger than a thickness of the first magnetic layer in the stack direction. This can effectively prevent disturbance of the magnetization direction of the third magnetic layer due to the electric current for varying the magnetization direction of the first magnetic layer, and stably retain the magnetization direction of the third magnetic layer.

The magnetoresistive effect element may further comprise an antiferromagnetic layer containing an antiferromagnetic material and provided on a surface opposite to a surface of the second magnetic layer opposed to the first magnetic layer. In another configuration, the magnetoresistive effect element may further comprise a fourth magnetic layer containing a ferromagnetic material and provided above a surface opposite to a surface of the second magnetic layer opposed to the first magnetic layer, and a second nonmagnetic conductive layer containing a nonmagnetic and electrically conductive material and provided between the second magnetic layer and the fourth magnetic layer. Either one of these configurations effects exchange coupling or antiferromagnetic coupling between the antiferromagnetic layer or the fourth magnetic layer and the second magnetic layer, and can stably retain the magnetization direction of the second magnetic layer.

The magnetoresistive effect element may also be characterized in that a thickness of the nonmagnetic insulating layer in the stack direction is not more than 0.8 nm. All the layers of the magnetoresistive effect element, except for the nonmagnetic insulating layer, are often made each containing an electrically conductive material. In this case, the electric resistance between the two ends in the stack direction of the magnetoresistive effect element is substantially determined by the electric resistance of the nonmagnetic insulating layer in the stack direction. By setting the thickness of the nonmagnetic insulating layer in the stack direction to not more than 0.8 nm, the electric resistance per cross section of 1 μm² perpendicular to the stack direction of the magnetoresistive effect element can be kept not more than 100Ω.

A magnetic memory according to the present invention is one comprising a plurality of storage areas, wherein each of the plurality of storage areas has one of the magnetoresistive effect elements described above. When the magnetic memory comprises one of the magnetoresistive effect elements described above, it is feasible to prevent erroneous writing in the TMR elements other than the object to be written, to facilitate achievement of higher integration, and to quickly and stably read out data stored in the magnetoresistive effect element.

The magnetoresistive effect element and magnetic memory according to the present invention are able to prevent erroneous writing and to facilitate achievement of higher integration.

### BRIEF DESCRIPTION OF THE DRAWINGS

FIG. 1 is a plan view of a magnetic memory.

FIG. 2 is a sectional view of the magnetic memory shown in FIG. 1, cut on line I-I along a row direction.

FIG. 3 is a sectional view of the magnetic memory shown in FIGS. 1 and 2, cut on line II-II along a column direction.

FIG. 4 is an enlarged sectional view of a TMR element and a neighboring structure thereof.

FIG. 5 is a graph showing correlation between electric current and resistance in a TMR element.

FIGS. 6A, 6B, and 6C are views showing a method of producing a TMR element and a neighboring structure thereof.

FIGS. 7A, 7B, and 7C are views showing a method of producing a TMR element and a neighboring structure thereof.

FIG. 8 is a sectional view showing a configuration of a modification example of a TMR element.

FIG. 9 is a sectional view showing a configuration of a modification example of a TMR element.

FIG. 10 is a sectional view showing a configuration of a modification example of a TMR element.

FIG. 11 is a table showing the results of examples.

### DESCRIPTION OF THE PREFERRED EMBODIMENT

An embodiment of the magnetoresistive effect element and magnetic memory according to the present invention will be described below in detail with reference to the accompanying drawings. In the description of the drawings the same elements will be denoted by the same reference symbols, without redundant description.

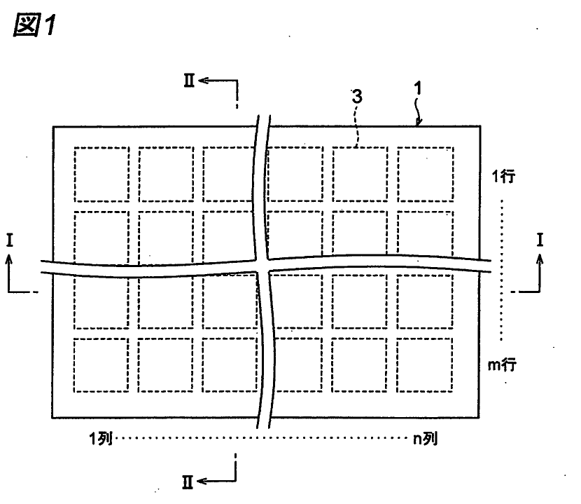

First described is a configuration of an embodiment of a magnetic memory provided with magnetoresistive effect elements according to the present invention. FIG. 1 is a plan view of magnetic memory 1 according to the present embodiment. The magnetic memory 1 has a plurality of storage areas 3. The plurality of storage areas 3 are arranged in a two-dimensional array of m rows and n columns (each of m and n is an integer of not less than 2). Each of the storage areas 3 has a magnetoresistive effect element such as a TMR element.

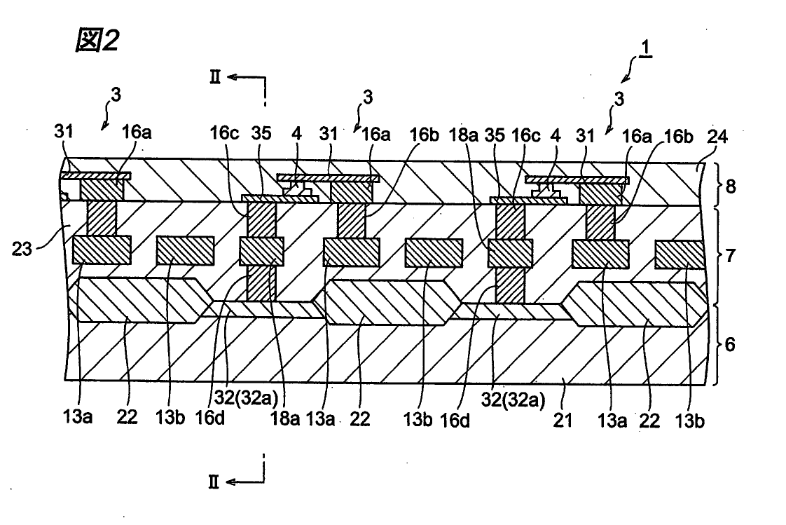

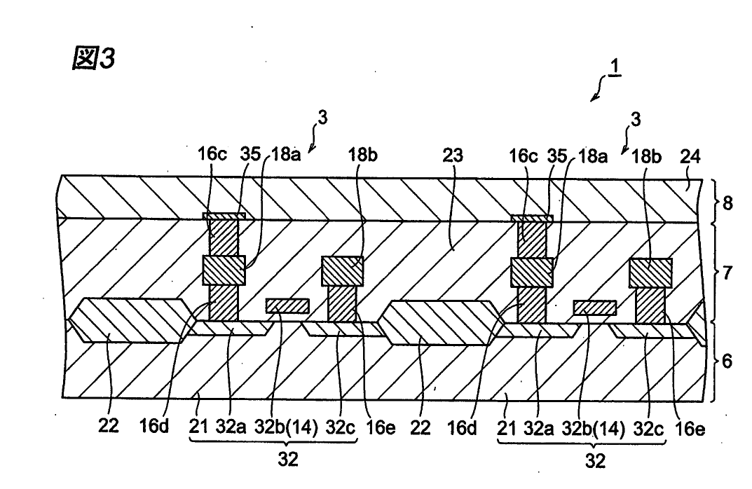

FIG. 2 is a sectional view of the magnetic memory 1 shown in FIG. 1, cut on line I-I along the row direction. FIG. 3 is a sectional view of the magnetic memory I shown in FIGS. 1 and 2, cut on line II-II along the column direction. With reference to FIGS. 2 and 3, the magnetic memory 1 has a semiconductor layer 6, a wiring layer 7, and a magnetic material layer 8. The magnetic memory 1 has TMR elements 4, bit lines 13a and 13b, word lines 14, a semiconductor substrate 21, and transistors 32.

The semiconductor layer 6 is a layer that includes the semiconductor substrate 21, that maintains the mechanical strength of the entire magnetic memory 1, and in that semiconductor devices such as transistors are formed. The magnetic material layer 8 is a layer in that structures of magnetic materials like TMR elements 4 are formed. The wiring layer 7 is provided between the semiconductor layer 6 and the magnetic material layer 8. The wiring layer 7 is a layer in that lines between areas like bit lines 13a, 13b and word lines 14 are formed. Also formed in the wiring layer 7 are wiring lines for establishing mutual electrical connections between the magnetic devices such as the TMR elements 4 formed in the magnetic material layer 8, the semiconductor devices such as the transistors formed in the semiconductor layer 6, the bit lines 13a, 13b, and the word lines 14.

First, the semiconductor layer 6 will be described. The semiconductor layer 6 has the semiconductor substrate 21, an insulating region 22, and transistors 32. The semiconductor substrate 21 is made, for example, of an Si substrate and is doped with a p-type or n-type impurity. The insulating region 22 is formed in the region other than the transistors 32 on the semiconductor substrate 21 and electrically isolates the transistors 32 in mutually adjacent storage areas 3 from each other. The insulating region 22 is made, for example, of an insulating material like SiO₂.

With reference to FIG. 3, each transistor 32 is comprised of a drain region 32a and a source region 32c with a conductivity type opposite to that of the semiconductor substrate 21, a gate electrode 32b, and a part of the semiconductor substrate 21. The drain region 32a and source region 32c are formed, for example, by doping the neighborhood of the surface of the Si substrate with an impurity having the conductivity type opposite to that of the semiconductor substrate 21. The semiconductor substrate 21 lies between the drain region 32a and the source region 32c, and the gate electrode 32b is placed above the semiconductor substrate 21. In the transistor 32 constructed in this configuration, when a voltage is applied to the gate electrode 32b, the drain region 32a and source region 32c turn into an electrically conducting state.

Next, the magnetic material layer 8 will be described. With reference to FIG. 2, the magnetic material layer 8 has TMR elements 4, an insulating region 24, and electrodes 31 and 35. In the magnetic material layer 8, the insulating region 24 occupies the regions other than the below-described configuration (TMR elements 4 and electrodes 31 and 35) and other wiring lines. A material for the insulating region 24 can be an insulating material like SiO₂ as the insulating region 22 of the semiconductor layer 6 was.

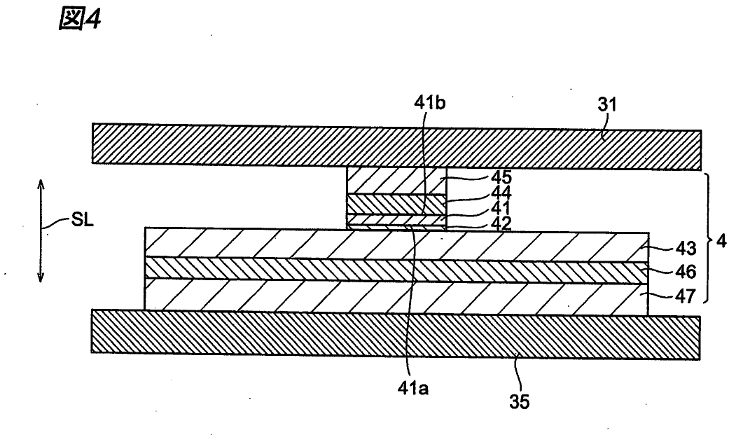

FIG. 4 is an enlarged sectional view of a TMR element 4 and a neighboring structure thereof. FIG. 4 shows a cross section along the row direction of a storage area 3. With reference to FIG. 4, a TMR element 4 is located between electrodes 31 and 35 arranged in the stack direction, and has a first magnetic layer 41, a nonmagnetic insulating layer 42, a second magnetic layer 43, a first nonmagnetic conductive layer 44, a third magnetic layer 45, a second nonmagnetic conductive layer 46, and a fourth magnetic layer 47.

The first magnetic layer 41 is a layer in that a bit of binary data (e.g., 0 or 1) is recorded by a direction of magnetization inside. Namely, the first magnetic layer 41 contains a ferromagnetic material and is arranged so that when the density of the electric current flowing in the stack direction (arrow SL in the drawing) exceeds a certain threshold, the internal magnetization direction is varied (or reversed) according to the spin direction of the electric current. The smaller the area of the cross section of the first magnetic layer 41 perpendicular to the stack direction SL, the smaller the value of the electric current necessary for reversal of the magnetization direction becomes. For this reason, the sectional area of the first magnetic layer 41 perpendicular to the stack direction SL is preferably a small value, e.g., not more than 0.01 μm². If the sectional area of the first magnetic layer 41 perpendicular to the stack direction SL is over 0.01 μm² the current value necessary for reversal of the magnetization direction will increase, so as to make recording of binary data difficult. The smaller the thickness of the first magnetic layer 41 along the stack direction SL, the smaller the current value necessary for reversal of the magnetization direction becomes. For this reason, the thickness of the first magnetic layer 41 along the stack direction SL is preferably a small value, e.g., not more than 0.01 μm. If the thickness of the first magnetic layer 41 along the stack direction SL is over 0.01 μm, the current value necessary for reversal of the magnetization direction will increase, so as to make recording of binary data difficult. A material for the first magnetic layer 41 can be selected, for example, from ferromagnetic materials such as Co, CoFe, NiFe, NiFeCo, and CoPt, or from materials as arbitrary combinations among them.

The second magnetic layer 43 is a layer in that the magnetization direction is kept constant. The second magnetic layer 43 contains a ferromagnetic material and is provided above one surface 41a of the first magnetic layer 41. The second magnetic layer 43 is preferably configured as follows: in order to prevent the magnetization direction inside the second magnetic layer 43 from being disturbed by the electric current for reversal of the magnetization direction of the first magnetic layer 41, at least one of the area of the cross section perpendicular to the stack direction SL and the thickness along the stack direction SL is larger than that of the first magnetic layer 41. This configuration requires a very large electric current for varying the magnetization direction inside the second magnetic layer 43, so as to reduce disturbance of the magnetization direction inside the second magnetic layer 43 due to the electric current for reversal of the magnetization direction of the first magnetic layer 41. For example, when the sectional area of the second magnetic layer 43 perpendicular to the stack direction SL is not less than double the sectional area of the first magnetic layer 41 perpendicular to the stack direction SL, the magnetization direction of the second magnetic layer 43 can be stably retained. A material for the second magnetic layer 43 can also be selected, for example, from the ferromagnetic materials such as Co, CoFe, NiFe, NiFeCo, and CoPt, or from materials as arbitrary combinations among them, as in the case of the first magnetic layer 41.

The nonmagnetic insulating layer 42 is provided between the first magnetic layer 41 and the second magnetic layer 43 and contains a nonmagnetic and insulating material. The nonmagnetic insulating layer 42 is formed between the first magnetic layer 41 and the second magnetic layer 43 and in a smaller thickness than these layers. When the nonmagnetic insulating layer 42 lies between the first magnetic layer 41 and the second magnetic layer 43, the tunneling magnetoresistive (TMR) effect is produced between the first magnetic layer 41 and the second magnetic layer 43. Namely, an electric resistance according to the relative relation (parallel or antiparallel) between the magnetization direction of the first magnetic layer 41 and the magnetization direction of the second magnetic layer 43 appears between the first magnetic layer 41 and the second magnetic layer 43. A material suitable for the nonmagnetic insulating layer 42 can be selected, for example, from oxides or nitrides of metals such as Al, Zn, and Mg.

The first nonmagnetic conductive layer 44 and third magnetic layer 45 are layers for injecting a spin-polarized current with a spin direction biased, into the first magnetic layer 41. The third magnetic layer 45 contains a ferromagnetic material and is provided above the other surface 41b of the first magnetic layer 41. The magnetization direction of the third magnetic layer 45 is retained constant. The third magnetic layer 45 is preferably configured as follows: in order to prevent the magnetization direction inside the third magnetic layer 45 from being disturbed by the electric current for reversal of the magnetization direction of the first magnetic layer 41, the thickness of the third magnetic layer 45 along the stack direction SL is larger than the thickness of the first magnetic layer 41. This configuration requires a very large electric current for varying the magnetization direction inside the third magnetic layer 45, so as to reduce disturbance of the magnetization direction inside the third magnetic layer 45 due to the electric current for reversal of the magnetization direction of the first magnetic layer 41. The first nonmagnetic conductive layer 44 contains a nonmagnetic and electrically conductive material and is provided on the other surface 41b of the first magnetic layer 41 and between the first magnetic layer 41 and the third magnetic layer 45. A material for the third magnetic layer 45 can be selected, for example, from the ferromagnetic materials such as Co, CoFe, NiFe, NiFeCo, and CoPt, or from materials as arbitrary combinations among them, as in the case of the first magnetic layer 41. A material for the first nonmagnetic conductive layer 44 can be selected, for example, from nonmagnetic conductive materials such as Ru, Rh, Ir, Cu, and Ag, or from materials as arbitrary combinations among them.

The second nonmagnetic conductive layer 46 and fourth magnetic layer 47 are layers (Pin layers) for retaining the magnetization direction of the second magnetic layer (Pinned layer) 43 along a fixed direction. The fourth magnetic layer 47 contains a ferromagnetic material and is provided above a surface opposite to a surface of the second magnetic layer 43 opposed to the first magnetic layer (Free layer) 41. The magnetization direction of the fourth magnetic layer 47 is fixed. The second nonmagnetic conductive layer 46 contains a nonmagnetic and electrically conductive material and is provided above one surface 41a of the first magnetic layer 41 and between the second magnetic layer 43 and the fourth magnetic layer 47. Since the fourth magnetic layer 47 establishes antiferromagnetic coupling with the second magnetic layer 43 through the second nonmagnetic conductive layer 46, the magnetization direction of the second magnetic layer 43 can be further stabilized. In addition, since this configuration can prevent an impact of a static magnetic field from the second magnetic layer 43 on the first magnetic layer 41, it can facilitate the magnetization reversal of the first magnetic layer 41. A material for the fourth magnetic layer 47 can be selected, for example, from the ferromagnetic materials such as Co, CoFe, NiFe, NiFeCo, and CoPt, or from materials as arbitrary combinations among them, as in the case of the first magnetic layer 41. A material for the second nonmagnetic conductive layer 46 can be selected, for example, from the nonmagnetic conductive materials such as Ru, Rh, Ir, Cu, and Ag, or from materials as arbitrary combinations among them. The thickness of the second nonmagnetic conductive layer 46 is preferably not more than 2 nm in order to achieve strong antiferromagnetic coupling between the second magnetic layer 43 and the fourth magnetic layer 47.

In the TMR element 4 having the above configuration, as shown in the later-described examples, the materials and thicknesses of the respective layers are determined so that the electric resistance between two ends in the stack direction per cross section of 1 μm² perpendicular to the stack direction SL in the region between the two end faces crossing the stack direction SL, i.e., between the end face on the third magnetic layer 45 side and the end face on the fourth magnetic layer 47 side is not less than 1Ω nor more than 100Ω (more preferably, not less than 1Ω nor more than 10Ω). Since each of all the layers except for the nonmagnetic insulating layer 42 among the layers in TMR element 4 includes the electrically conductive material, the electric resistance between the two ends of TMR element 4 is substantially determined by the electric resistance of the nonmagnetic insulating layer 42.

An electrode 31 is provided on the third magnetic layer 45 of each TMR element 4. The electrode 31 is made of an electrically conductive metal and extends in the row direction of storage area 3. The electrode 31 is electrically connected to the third magnetic layer 45 and is also electrically connected through a vertical line 16a to a bit line 13a inside the wiring layer 7 (cf. FIG. 2). The fourth magnetic layer 47 of each TMR element 4 is provided on an electrode 35 and is electrically connected to the electrode 35. The electrode 35 is electrically connected through a line (described later) provided inside the wiring layer 7, to a transistor 32. When a write current or a read current is allowed to flow between electrode 31 and electrode 35, the electric current can be made to flow along the stack direction SL and through the TMR element 4.

Referring again to FIGS. 2 and 3, the wiring layer 7 will be described. The wiring layer 7 has the insulating region 23, bit lines 13a and 13b, word lines 14, and a plurality of vertical lines and horizontal lines. In the wiring layer 7, the insulating region 23 occupies all the regions except for the lines. A material for the insulating region 23 can be an insulating material like SiO₂ as that for the insulating region 22 of the semiconductor layer 6 was. A material for the vertical lines can be, for example. W, and a material for the bit lines 13a and 13b, word lines 14, and horizontal lines can be, for example, Al.

The bit lines 13a and 13b are wires arranged corresponding to respective columns of storage areas 3. A bit line 13a is electrically connected through vertical lines 16a and 16b to electrodes 31 of respective storage areas 3 in a corresponding column. This results in electrically connecting the bit line 13a to one end of each TMR element 4 on the third magnetic layer 45 side. A bit line 13b is electrically connected to source regions 32c of transistors 32 of respective storage areas 3 in a corresponding column. Specifically, a bit line 13b is electrically connected through horizontal lines 18b shown in FIG. 3, to vertical lines 16e, while each vertical line 16e is in ohmic contact with the source region 32c of transistor 32.

The word lines 14 are wires arranged corresponding to the respective rows of storage areas 3. A word line 14 is electrically connected to gate electrodes 32b being control terminals of transistors 32 of respective storage areas 3 in a corresponding row. In the present embodiment parts of word line 14 also serve as gate electrodes 32b of transistors 32. Namely, each gate electrode 32b shown in FIG. 3 is constructed of a part of word line 14 extending in the row direction of storage area 3.

An electrode 35 in the magnetic material layer 8 is electrically connected through a vertical line 16c and a horizontal line 18a in the wiring layer 7 to a vertical line 16d, while the vertical line 16d is in ohmic contact with the drain region 32a of transistor 32. This results in electrically connecting one end of each TMR element 4 on the fourth magnetic layer 47 side to the drain region 32a of transistor 32.

The magnetic memory 1 having the above configuration is able to operate as follows. Namely, for writing binary data in a certain storage area 3, a control voltage is applied to a word line 14 passing the storage area 3. This results in applying the control voltage to the gate electrode 32b of the transistor 32 in the storage area 3, so as to establish an electrically conducting state between the drain region 32a and the source region 32c. Furthermore, a positive or negative write current according to the binary data is supplied between the bit line 13a and bit line 13b passing the storage area 3. This reverses the magnetization direction of the first magnetic layer 41 of the TMR element 4.

For reading binary data out of a storage area 3, a control voltage is applied to a word line 14 passing the storage area 3, and a read current in such a magnitude as not to reverse the magnetization direction of the first magnetic layer 41 is supplied between bit line 13a and bit line 13b. By measuring a resistance between the two end faces of the TMR element 4 crossing the stack direction SL, the binary data stored in the storage area 3 can be read out. The resistance between the two ends of the TMR element 4 can be measured, for example, by measuring a voltage drop amount in the TMR element 4 with supply of the read current.

The operation of the TMR element 4 in the present embodiment will be described in further detail. First described is the spin polarization action by the first nonmagnetic conductive layer 44 and third magnetic layer 45 on the occasion of writing binary data in the TMR element 4. Normally, in an electric current flowing along the stack direction SL in the TMR element 4, an energy state of an electron with an upward spin (up spin) is different from an energy state of an electron with a downward spin (down spin). Therefore, there is a difference between a transmittance (or reflectance) of electrons with the up spin and a transmittance (or reflectance) of electrons with the down spin, at a junction (interface) between a ferromagnetic layer and a nonmagnetic layer. This causes the spin direction of electrons flowing from the third magnetic layer 45 side into the first magnetic layer 41 to be biased toward the magnetization direction of the third magnetic layer 45 and causes the spin direction of electrons flowing from the second magnetic layer 43 side into the first magnetic layer 41 to be biased toward the direction opposite to the magnetization direction of the third magnetic layer 45. In this manner, a spin-polarized current with the spin direction different according to the direction of the electric current is injected into the first magnetic layer 41.

When a spin-polarized current is injected into the first magnetic layer 41, exchange interaction occurs between spin-polarized electrons included in this spin-polarized current and electrons inside the first magnetic layer 41, and the magnetization direction of the first magnetic layer 41 is varied by a torque generated between these electrons. Since the spin direction of the spin-polarized electrons flowing from the third magnetic layer 45 side into the first magnetic layer 41 is opposite to the spin direction of the spin-polarized electrons flowing from the second magnetic layer 43 side into the first magnetic layer 41, a direction of the variation in the magnetization direction of the first magnetic layer 41 (i.e., a direction of reversal) is determined by the flowing direction of the spin-polarized current. Therefore, the magnetization direction of the first magnetic layer 41 turns into a direction according to the direction of the electric current flowing in the TMR element 4, and therefore binary data can be written by the plus or minus of the write current supplied to the TMR element 4.

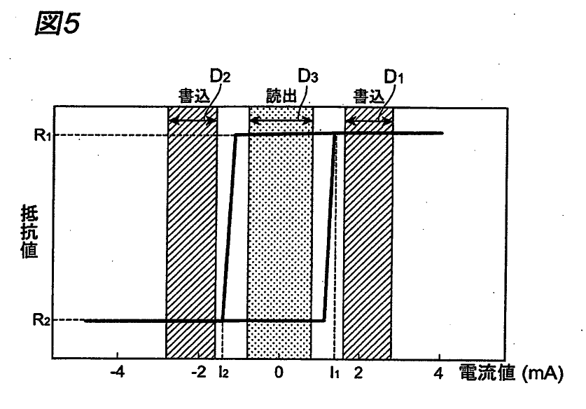

FIG. 5 is a graph showing the correlation between electric current and resistance in the TMR element 4. In the graph of FIG. 5, for example, positive current values are taken where the electric current flows from the fourth magnetic layer 47 side to the third magnetic layer 45 side and negative current values are taken where the electric current flows from the third magnetic layer 45 side to the fourth magnetic layer 47 side. Supposing at the present moment the magnetization direction of the first magnetic layer 41 is parallel to the magnetization direction of the second magnetic layer 43, the resistance between the two ends of TMR element 4 is a relatively small value R₂. As the electric current (absolute value) flowing in the TMR element 4 is gradually increased along the positive direction from 0 mA, the magnetization direction of the first magnetic layer 41 is completely reversed with the electric current over a threshold (critical current) I₁. Therefore, the magnetization direction of the first magnetic layer 41 becomes antiparallel to the magnetization direction of the second magnetic layer 43, and the resistance between the two ends of TMR element 4 increases to a value R₁ larger than the value R₂ by the TMR effect. Conversely, as the electric current (absolute value) flowing in the TMR element 4 is gradually increased along the negative direction from 0 mA and from the state in which the magnetization direction of the first magnetic layer 41 is antiparallel to the magnetization direction of the second magnetic layer 43, the magnetization direction of the first magnetic layer 41 is again reversed with the current value over a threshold (critical current) 12. Therefore, the magnetization direction of the first magnetic layer 41 becomes parallel to the magnetization direction of the second magnetic layer 43, and the resistance between the two ends of TMR element 4 reduces to the value R₂ smaller than the value R₁ by the TMR effect.

It is seen from the above that a bit of binary data (e.g., 0) can be written in the TMR element 4 by supplying a positive write current with the absolute value larger than the threshold I₁ (e.g., which is included in the range D₁ shown in FIG. 5) to the TMR element 4. The other bit of binary data (e.g., 1) can be written in the TMR element 4 by supplying a negative write current with the absolute value larger than the threshold 12 (e.g., which is included in the range D₂) to the TMR element 4. The binary data written in the TMR element 4 can be read out by supplying a positive or negative read current with the absolute value smaller than the thresholds I₁, I₂ (e.g., which is included in the range D₃) to the TMR element 4, so as not to reverse the magnetization direction of the first magnetic layer 41.

The effects of the TMR element and magnetic memory 1 of the present embodiment described above will be described. In the TMR element 4 of the present embodiment, the magnetization direction of the first magnetic layer 41 can be varied by direct flow of the electric current in the TMR element 4, instead of the external magnetic field such as the magnetic field of the electric current. In addition, the spin-polarized current is generated by the first nonmagnetic conductive layer 44 and the third magnetic layer 45, so that the magnetization direction of the first magnetic layer 41 can be varied by the relatively small write current. With the TMR element 4 and magnetic memory 1 of the present embodiment, therefore, there is no leakage of the magnetic field to the other TMR elements than the TMR element as an object to be written, and erroneous writing can be effectively prevented.

Since in the TMR element 4 of the present embodiment the magnetization direction of the first magnetic layer 41 is reversed by the spin-polarized current, the demagnetizing field does not increase inside the first magnetic layer 41 and the electric current necessary for reversal of the magnetization direction becomes smaller with decrease in the planar size of the first magnetic layer 41. With the TMR element 4 and magnetic memory 1 of the present embodiment, therefore, it becomes easy to achieve miniaturization of TMR element 4 and to achieve higher integration of magnetic memory 1.

In the TMR element 4 of the present embodiment the nonmagnetic insulating layer 42 is provided between the first magnetic layer 41 with the varying magnetization direction and the second magnetic layer 43 with the fixed magnetization direction. This produces the TMR effect between the first magnetic layer 41 and the second magnetic layer 43, so that the resistance change rate (i.e., (R₂-R₁)/R₁ in the graph shown in FIG. 5) by the variation of the magnetization direction of the first magnetic layer 41 can be made relatively large. With the TMR element 4 and magnetic memory 1 of the present embodiment, therefore, it is feasible to quickly and stably read out the data stored by the magnetization direction of the first magnetic layer 41.

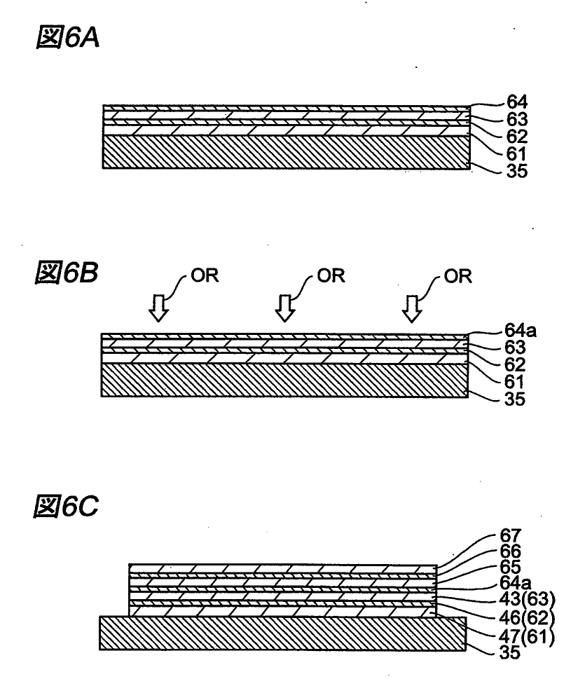

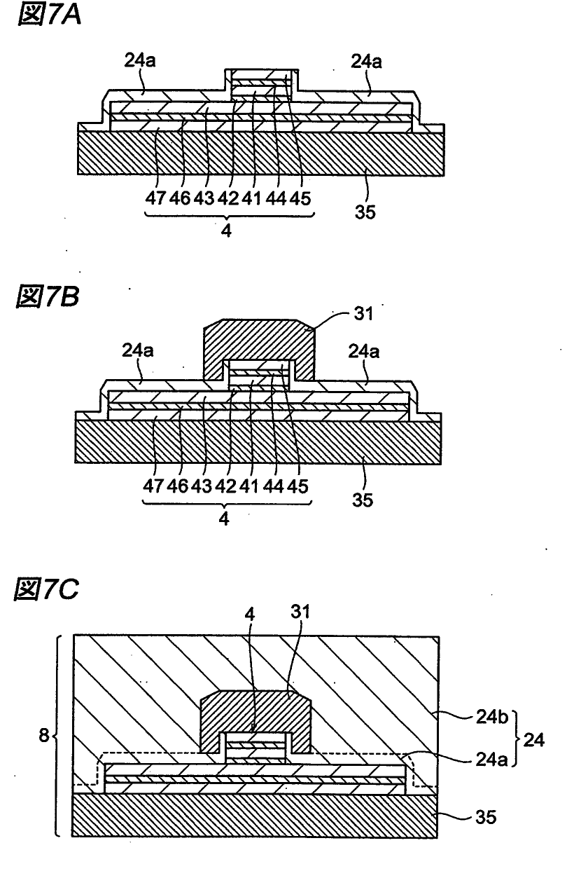

A production method of a TMR element 4 and a neighboring structure thereof out of a production method of magnetic memory 1 of the present embodiment will be described with reference to FIGS. 6A, 6B, and 6C and FIGS. 7A, 7B, and 7C. FIGS. 6A, 6B, 6C and FIGS. 7A, 7B, 7C all are cross sections along line I-I in FIG. 1 and show production steps thereof in order.

First, as shown in FIG. 6A, electrode 35 of Cu is formed on a wiring layer. Then a high-vacuum sputtering system is used to deposit a CoFe layer 61 intended for the fourth magnetic layer, a Ru layer 62 intended for the second nonmagnetic conductive layer, a CoFe layer 63 intended for the second magnetic layer, and a metal layer 64 in order on the electrode 35. At this time, a material of the metal layer 64 may be at least one kind out of Al, Zn, and Mg, for example. Subsequently, as shown in FIG. 6B, the metal layer 64 is oxidized by oxygen radical OR to form a tunnel insulating layer 64a intended for the nonmagnetic insulating layer. Thereafter, as shown in FIG. 6C, a CoFe layer 65 intended for the first magnetic layer, a Cu layer 66 intended for the first nonmagnetic conductive layer, a CoFe layer 67 intended for the third magnetic layer, and a Ta protecting layer (not shown) are sequentially deposited on the tunnel insulating layer 64a. Subsequently, a resist mask is formed on the Ta protecting layer, and ion milling is performed to etch the CoFe layer 61, Ru layer 62, and CoFe layer 63, thereby forming the fourth magnetic layer 47, second nonmagnetic conductive layer 46, and second magnetic layer 43.

After that, another resist mask is again formed on the Ta protecting layer, and ion milling is performed to etch the tunnel insulating layer 64a, CoFe layer 65, Cu layer 66, and CoFe layer 67, thereby forming the nonmagnetic insulating layer 42, first magnetic layer 41, first nonmagnetic conductive layer 44, and third magnetic layer 45, as shown in FIG. 7A. The TMR element 4 is formed in this manner. After the formation of the TMR element 4, a CVD system is used to form an SiO₂ insulating layer 24a, except for the region on the third magnetic layer 45, for example, with Si(OC₂H₅)₄. After this step, the resist mask is removed.

Subsequently, a resist mask with an aperture according to the planar shape of electrode 31 is formed on the SiO₂ insulating layer 24a. Then a Ti layer and a Cu layer are sequentially deposited by sputtering and thereafter the resist mask is removed. In this manner, as shown in FIG. 7B, the electrode 31 is formed on the TMR element 4.

In the last step, as shown in FIG. 7C, an SiO₂ insulating layer 24b of the same material as the SiO₂ insulating layer 24a is formed over the entire surface on the SiO₂ insulating layer 24a and on the electrode 31 by CVD. This forms the insulating region 24 consisting of the SiO₂ insulating layers 24a and 24b, thus completing the magnetic material layer 8.

### MODIFICATION EXAMPLES

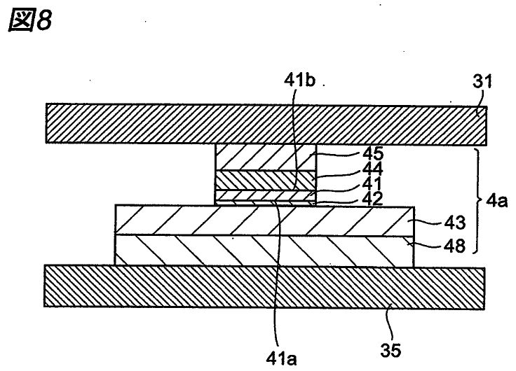

Modification examples of TMR element 4 and magnetic memory 1 of the present embodiment will be described below. FIGS. 8 to 10 are sectional views showing configurations of TMR elements 4a-4c according to the respective modification examples. By adopting the TMR elements 4a-4c according to the modification examples instead of the TMR element 4 of the above embodiment, the same effects can be achieved as those with the TMR element 4 and magnetic memory 1 of the above embodiment.

First, referring to FIG. 8, the TMR element 4a is composed of a first magnetic layer 41, a nonmagnetic insulating layer 42, a second magnetic layer 43, a first nonmagnetic conductive layer 44, a third magnetic layer 45, and an antiferromagnetic layer 48. The TMR element 4a of the present modification example is different from the TMR element 4 of the above embodiment in that the antiferromagnetic layer 48 is provided instead of the second nonmagnetic conductive layer 46 and the fourth magnetic layer 47.

The antiferromagnetic layer (Exchange layer; Pin layer) 48 is a layer for retaining the magnetization direction of the second magnetic layer (Pinned layer) 43 along a fixed direction. The antiferromagnetic layer 48 contains an antiferromagnetic material and is provided on a surface opposite to a surface of the second magnetic layer 43 opposed to the first magnetic layer (Free layer) 41. Then exchange coupling occurs between the antiferromagnetic layer 48 and the second magnetic layer 43 to stabilize the magnetization direction of the second magnetic layer 43. A material for the antiferromagnetic layer 48 can be selected from IrMn, PtMn, FeMn, PtPdMn, and NiO, or from materials as arbitrary combinations among them.

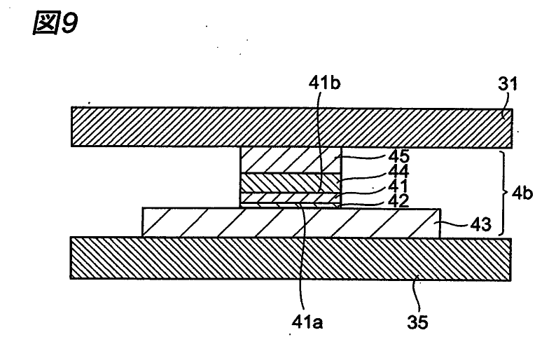

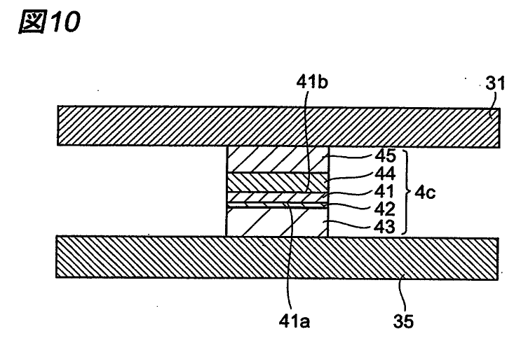

Next, referring to FIGS. 9 and 10, the TMR elements 4b and 4c are comprised of a first magnetic layer 41, a nonmagnetic insulating layer 42, a second magnetic layer 43, a first nonmagnetic conductive layer 44, and a third magnetic layer 45. The TMR elements 4b and 4c of these modification examples are different from the TMR element 4 of the above embodiment in that the TMR elements do not have the second nonmagnetic conductive layer 46 and fourth magnetic layer 47 and in that the second magnetic layer 43 is in contact with the electrode 35. Even in these cases where the element is not provided with the layers for stably retaining the magnetization direction of the second magnetic layer 43, the magnetization direction of the second magnetic layer 43 can be kept fixed by making the area of the cross section of the second magnetic layer 43 perpendicular to the stack direction, larger than that of the first magnetic layer 41, as shown in FIG. 9, or by making the thickness of the second magnetic layer 43 in the stack direction larger than that of the first magnetic layer 41, as shown in FIG. 10.

### EXAMPLES

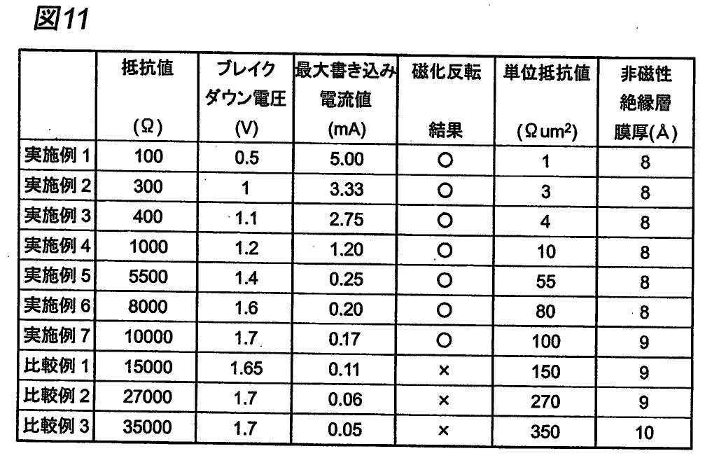

Subsequently, examples of the TMR element of the above embodiment will be described. FIG. 11 is a table showing the results of the examples. In the examples, a plurality of TMR elements with different electric resistances between the two ends were produced, breakdown voltages were measured for these TMR elements, and it was checked whether magnetization reversal occurred before breakdown of each TMR element. The breakdown voltage stated herein means a voltage value at which the nonmagnetic insulating layer fails to function, so as to make the first magnetic layer and the second magnetic layer short-circuit. In the examples the electric resistances between the two ends were varied by change in the thickness of the nonmagnetic insulating layer among the plurality of TMR elements. In the examples, the planar shape of the TMR elements was square and the length on each side thereof was 0.1 μm.

Examples 1-7 were the TMR elements with the respective electric resistances between the two ends thereof being 100Ω, 300Ω, 400Ω, 1 kΩ, 5.5 kΩ, 8 kΩ, and 10 kΩ (i.e., the respective electric resistances per cross section of 1 μm² perpendicular to the stack direction being 1Ω, 3Ω, 4Ω, 10Ω, 55Ω, 80Ω, and 100Ω) and showed the breakdown voltages of 0.5 V, 1 V, 1.1 V, 1.2 V, 1.4 V, 1.6 V, and 1.7 V, respectively. The magnetization direction of the first magnetic layer was well reversed in each of Examples 1 to 7. In each of Examples 1-7 the thickness of the nonmagnetic insulating layer was 8 Å-9 Å (0.8 nm-0.9 nm). Maximum write currents immediately before breakdown were 5 mA, 3.33 mA, 2.75 mA, 1.2 mA, 0.25 mA, 0.2 mA, and 0.17 mA, respectively.

Furthermore, Comparative Examples 1-3 were TMR elements with the respective electric resistances between the two ends thereof being 15 kΩ, 27 kΩ, and 35 kΩ (i.e., the respective electric resistances per cross section of 1 μm² perpendicular to the stack direction being 150Ω, 270Ω, and 350Ω), and showed the breakdown voltages of 1.65 V, 1.7 V, and 1.7 V, respectively. However, the reversal of the magnetization direction of the first magnetic layer was not confirmed in each of Comparative Examples 1 to 3. In each of Comparative Examples 1-3 the thickness of the nonmagnetic insulating layer was 9 Å-10 Å (0.9 nm-1.0 nm). Maximum write currents immediately before breakdown were 0.11 mA, 0.06 mA, and 0.05 mA, respectively.

In the examples, the magnetization direction of the first magnetic layer was well reversed when the electric resistance between the two ends of the TMR element was not less than 1 Ωμm² nor more than 100 Ωμm². In contrast to it, the reversal of the magnetization direction of the first magnetic layer was not confirmed when the electric resistance between the two ends of the TMR element was over 100 Ωμm². The reason for it is presumably as follows. Namely, when the electric resistance between the two ends of the TMR element is over 100 Ωμm², the element temperature increases by virtue of the write current flowing inside the TMR element, to induce significant deterioration of the element due to electromigration. It is then presumed that further increase of the electric resistance broke the nonmagnetic insulating layer before the reversal of the magnetization direction of the first magnetic layer so as to make the first magnetic layer and the second magnetic layer short-circuit.

When the electric resistance between the two ends of the TMR element is smaller than 1 Ωμm², the thickness of the nonmagnetic insulating layer is so small as to increase a leak current between the first magnetic layer and the second magnetic layer. For this reason, the magnetoresistance change rate of the TMR element becomes suddenly lowered to decrease the output in reading of data (e.g., the voltage between the two ends), which makes reading of data difficult.

The above verified that when the electric resistance between the two end faces crossing the stack direction of the TMR element was not less than 10 Ωμm² nor more than 100 Ωμm², the effects based on the TMR effect were achieved as well while suitably effecting the magnetization reversal by the spin-polarized current.

Each of all the layers of the TMR element, except for the nonmagnetic insulating layer, contains the electrically conductive material. Therefore, the electric resistance between the both ends in the stack direction of the TMR element is substantially determined by the electric resistance of the nonmagnetic insulating layer in the stack direction. It was then confirmed by the examples that the electric resistance of the TMR element was kept not more than 100 Ωμm² when the thickness of the nonmagnetic insulating layer in the stack direction was not more than 0.8 nm.

What is claimed is:

1. A magnetoresistive effect element comprising:
a first magnetic layer which contains a ferromagnetic material and a magnetization direction of which varies according to a density and a spin direction of an electric current flowing in a stack direction;
a second magnetic layer which contains a ferromagnetic material, which is provided above one surface of the first magnetic layer, and a magnetization direction of which is fixed;
a nonmagnetic insulating layer which contains a nonmagnetic and insulating material and which is provided between the first magnetic layer and the second magnetic layer;
a third magnetic layer which contains a ferromagnetic material, which is provided above another surface of the first magnetic layer, and a magnetization direction of which is fixed; and
a first nonmagnetic conductive layer which contains a nonmagnetic and electrically conductive material and which is provided between the first magnetic layer and the third magnetic layer,
wherein an electric resistance between two ends in the stack direction per cross section of 1 μm² perpendicular to the stack direction is not less than 1Ω nor more than 100Ω.

2. The magnetoresistive effect element according to claim 1, wherein a thickness of the second magnetic layer in the stack direction is larger than a thickness of the first magnetic layer in the stack direction.

3. The magnetoresistive effect element according to claim 1, wherein a thickness of the third magnetic layer in the stack direction is larger than a thickness of the first magnetic layer in the stack direction.

4. The magnetoresistive effect element according to claim 1, wherein an area of a cross section of the second magnetic layer perpendicular to the stack direction is larger than an area of a cross section of the first magnetic layer perpendicular to the stack direction.

5. The magnetoresistive effect element according to claim 1, further comprising an antiferromagnetic layer containing an antiferromagnetic material and provided on a surface opposite to a surface of the second magnetic layer opposed to the first magnetic layer.

6. The magnetoresistive effect element according to claim 1, further comprising:
a fourth magnetic layer containing a ferromagnetic material and provided above a surface opposite to a surface of the second magnetic layer opposed to the first magnetic layer; and
a second nonmagnetic conductive layer containing a nonmagnetic and electrically conductive material and provided between the second magnetic layer and the fourth magnetic layer.

7. The magnetoresistive effect element according to claim 1, wherein a thickness of the nonmagnetic insulating layer in the stack direction is not more than 0.8 nm.

8. A magnetic memory comprising a plurality of storage areas,
wherein each of the plurality of storage areas has the magnetoresistive effect element as set forth in claim 1.
